(19) United States
(12) Patent Application Publication
(10) Pub. No.: US 2012/0164854 A1
(43) Pub. Date: Jun. 28, 2012

(54) PACKAGING SUBSTRATE AND METHOD OF FABRICATING THE SAME

(75) Inventor: Ying-Tung Wang, Taoyuan (TW)

(73) Assignee: UNIMICRON TECHNOLOGY CORPORATION, Taoyuan (TW)

(21) Appl. No.: 13/236,855

(22) Filed: Sep. 20, 2011

(30) Foreign Application Priority Data
Dec. 24, 2010 (TW) 099145702

(51) Int. Cl. H01R 12/71; H05K 3/00

(52) U.S. Cl. 439/78; 29/829

(57) ABSTRACT

A packaging substrate is proposed, which includes: a circuit layer formed on a substrate and having conductive pads, an insulating protective layer formed on the substrate for covering the circuit layer and having openings for correspondingly exposing the conductive pads; copper bumps each having a connection portion formed in a corresponding one of the openings and electrically connected to a corresponding one of the conductive pads, and a protruding portion integrally connected to the connection portion and extending to a portion of the insulating protective layer surrounding the corresponding one of the openings, allowing the protruding portion to be greater in diameter than the connection portion, and a surface treatment layer having an electroplated nickel material formed on top surfaces of the protruding portions of the copper bumps, and an electroplated gold material formed on the electroplated nickel material. The surface treatment layer is not formed on side surfaces of the protruding portions, such that the thickness of the surface treatment layer is irrelevant to the diameter of the protruding portion.

### BACKGROUND OF THE INVENTION

1. Field of the Invention

This invention relates to packaging substrates and methods of fabricating the same, and, more particularly, to a packaging substrate having copper bumps and a method of fabricating the same.

2. Description of Related Art

With the rapid development of semiconductor packaging technology, modern semiconductor devices have various package types. In order to improve the electrical functionality, a surface treatment layer is formed on electrical contacts disposed on an outermost surface of a packaging substrate. Therefore, as a chip is installed on the packaging substrate, the reliability of electrical connection can be improved.

Referring to FIGS. 1A to 1E, cross-sectional views illustrating a method of fabricating a packaging substrate are shown according to the prior art.

As shown in FIG. 1A, a substrate body 10 is provided. The substrate 10 body has a circuit layer 100 formed thereon, and an insulating protective layer 11 formed on the substrate 10 body for covering the circuit layer 100. The circuit layer 100 has a plurality of conductive pads 100a. The insulating protective layer 11 is further formed with a plurality of opening 110 for exposing the conductive pads 100a.

As shown in FIG. 1B, a photoresist layer 13 is formed on the insulating protective layer 11. The photoresist layer 13 is then exposed and developed, to form a plurality of opening areas 130 for exposing the openings 110 and the portion of the insulating protective layer 11 surrounding the openings 110.

As shown in FIG. 1C, copper bumps 14 are formed in the opening areas 130. The copper bumps 14 each has a connection portion 140 formed on the conductive pad 100a in a corresponding one of the openings 110, and a protruding portion 141 integrally connected to the connection portion 140 and extending onto a portion of the insulating protective layer 11 surrounding the corresponding one of the openings 110.

As shown in FIG. 1D, the photoresist layer 13 is removed.

As shown in FIG. 1E, a top surface and a side surface of each of the protruding portions 141 are electrolessly plated to form a surface treatment layer 15. The surface treatment layer 15 has an electroplated nickel material 150 and an electroplated gold material 151 sequentially. During subsequent processes, the protruding portion 141 is electrically connected to a corresponding one of the electrode pads on a chip (not shown) by means of the surface treatment layer 15.

In the prior art, the surface treatment layer 15, being formed by the electroless plating technique, has a loose structure. Therefore, the surface treatment layer 15, unless it is thick enough, cannot satisfy the application demand. For example, the surface treatment layer 15 has to be as thick as 5 to 9 μm, in order to have a interfacial strength enough for installation of a chip during subsequent processes.

The contacts that the conventional packaging substrate uses for installation of a chip each have standard diameter, e.g., 95 μm. Accordingly, the protruding portion 141 of the copper bump 14 also has to have a standard diameter. Moreover, the exposure alignment error between each of the opening areas 130 of the photoresist layer 13 and each of the openings 110 of the insulating protective layer 11 is, for example, ±15 μm, while a diameter difference between each of the opening areas 130 and each of the openings 110 has to be greater than 30 μm. Accordingly, the opening 110 of the insulating protective layer 11 each can be at most 65 μm (i.e., the diameter of the connection portion 140).

However, the thickness s (e.g., 5 μm) of the surface treatment layer 15 must also be taken into consideration. As shown in FIG. 1E, the protruding portion 141 is assumed to have a diameter W of (95 μm−10 μm=) 85 μm, in order to comply with the overall diameter requirement. Accordingly, each of the opening areas 130 has to have a diameter W reduced from 95 μm to 85 μm. As a result, the exposure alignment error between the each of the opening areas 130 and each of the openings 110 is reduced to ±10 μm (a gap e between the opening area 130 and the opening 110 is reduced by 5 μm). Therefore, a more precise exposure process is required, which is adverse to the formation of the opening areas 130.

In light of the above arrangement, the exposure alignment error between each of the opening areas 130 and each of the openings 110 is preferably kept at ±15 μm, for effective formation of the opening areas 130. In the fabrication process shown in FIG. 1A, the diameter a of each of the openings 110 cannot exceed 55 μm. In the exposure process shown in FIG. 1B, the opening areas 130, even having the shorter diameter W of 85 μm, can still expose the openings 110, regardless of the alignment error. However, since the diameter a of each of the openings 110 is reduced by 10 μm, the connection portion 140 has a diameter a also reduced by 10 μm (i.e., being reduced from 65 μm to 55 μm), which results in the reduction of strength of the connection portion 140, which a chip is installed, the connection portion 140 is probably cracked due to its poor supporting strength.

In order to prevent the connection portion 140 from being cracked, the connection portion 140 must have a diameter a′ equal to 65 μm, as shown in FIG. 1E′. Accordingly, the opening area 130 also must have a diameter greater than 95 μm, so as for the opening areas 130 to expose the openings 110. As a result, an overall diameter R, which is equal to the diameter W′ (95 μm) of the protruding portion 141 added by the thickness s (5 μm) of the surface treatment layer 15, exceeds 105 μm, and thus does not comply with the specification requirement.

Therefore, how to overcome the problems of the prior art, and maintain the precision of the opening areas and the strength of the connection portion, is becoming one of the pressing issues in the art.

### SUMMARY OF THE INVENTION

In view of the above-mentioned problems of the prior art, the present invention provides a packaging substrate, comprising: a substrate body; a circuit layer formed on the substrate body and having a plurality of conductive pads, an insulating protective layer formed on the substrate body for covering the circuit layer, the insulating protective layer being formed with a plurality of openings for correspondingly exposing the conductive pads; a plurality of copper bumps each having a connection portion formed in a corresponding one of the openings and electrically connected to a corresponding one of the conductive pads, and a protruding portion integrally connected to the connection portion and further extending onto the insulating protective layer surrounding the corresponding one of the openings and being greater than the connection portion in diameter; and a surface treatment layer including an electroplated nickel material formed on top surfaces of the protruding portions of the copper bumps only and having a thickness of from 0.03 to 0.15 μm, and an electroplated gold material formed on the electroplated nickel material and having a thickness of from 0.20 to 0.80 μm.

In an embodiment of the present invention, the packaging substrate further comprises a conductive layer disposed between the copper bumps and the insulating protective layer, and disposed between the copper bumps and the conductive pads.

The present invention further provides a method of fabricating a packaging substrate, comprising: providing a substrate body formed with a circuit layer and an insulating protective layer that covers the circuit layer, wherein the insulating protective layer is formed with a plurality of openings for exposing the conductive pads of the circuit layer; forming a conductive layer on the insulating protective layer, opening walls of the openings, and the conductive pads; forming on the conductive layer a resist layer that has a plurality of opening areas for exposing the openings and the portion of the conductive layer surrounding the openings; forming on the conductive layer in the opening area a plurality of copper bumps, the copper bumps each including a connection portion formed in a corresponding one of the openings, and a protruding portion integrally connected to the connection portion and extending onto a portion of the insulating protective layer surrounding the corresponding one of the openings; electroplating a surface treatment layer on top surfaces of the protruding portions of the copper bumps, the surface treatment layer including an electroplated nickel material formed on the top surfaces of the protruding portions of the copper bumps only and being of a thickness of from 0.03 to 0.15 μm, and an electroplated gold material formed on the electroplated nickel material and being of a thickness of from 0.20 to 0.80 μm; and removing the resist layer and the conductive layer that is covered by the resist layer, to expose side surfaces of the protruding portions of the copper bumps.

In an embodiment of the present invention, the surface treatment layer further has an electroplated palladium material formed between the electroplated nickel material and the electroplated gold material, and being of a thickness of from 0.05 to 0.15 μm.

In an embodiment of the present invention, the protruding portion is greater in height than the connection portion.

In the packaging substrate and the method of fabricating the same according to the present invention, the surface treatment layer is formed by an electroplating process, and the resist layer is then removed, such that the surface treatment layer is not formed on the side surface of the protruding portion. Compared with the prior art, the protruding portion has a diameter irrelevant to a thickness of the surface treatment layer, and can still comply with the industry specification, even if the diameter is not reduced.

Since the protruding portion keeps its diameter unchanged, the alignment error between the opening area and the opening can have a value beneficial to the formation of the opening area.

Since the opening area also has an unchanged diameter, the diameter of the opening needs no reduction. Therefore, the diameter of the connection portion can have a value of keeping a required strength.

### BRIEF DESCRIPTION OF DRAWINGS

The invention can be more fully understood by reading the following detailed description of the preferred embodiments, with reference made to the accompanying drawings, wherein:

FIGS. 1A to 1E are cross-sectional views illustrating a method of fabricating a packaging substrate according to the prior art;

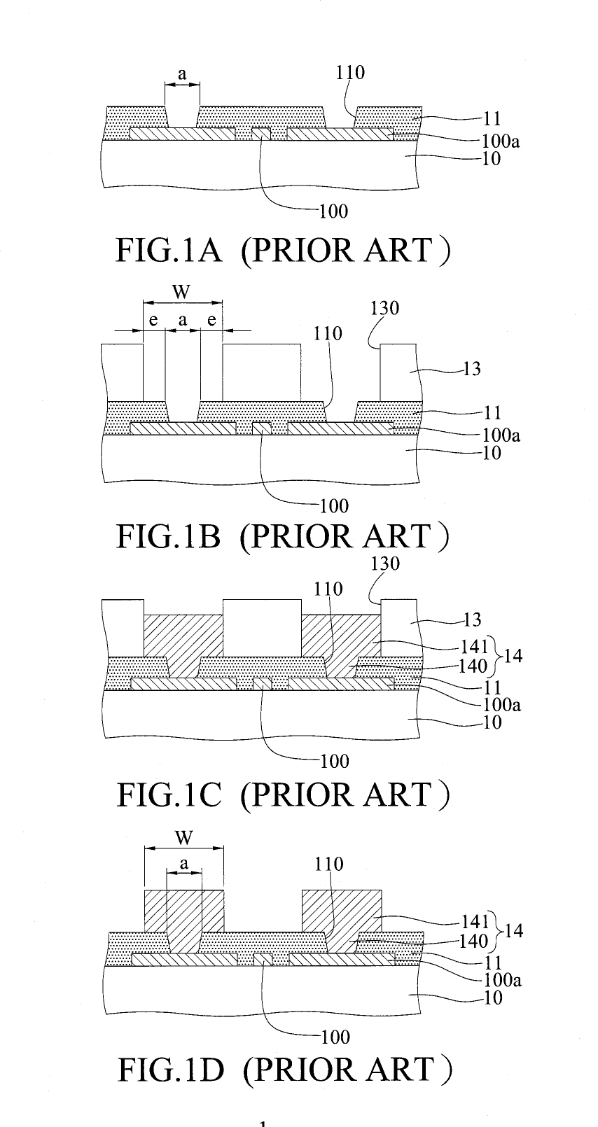

FIG. 1E′ is another embodiment of FIG. 1E;

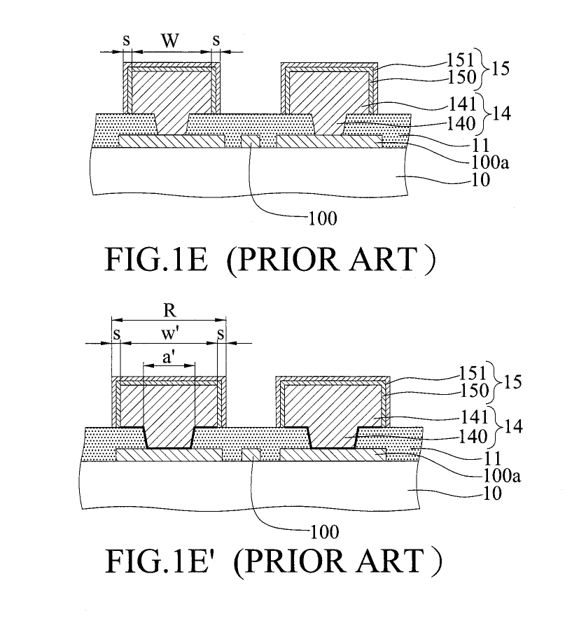

FIGS. 2A to 2E are cross-sectional views illustrating a method of fabricating a packaging substrate according to the present invention; and

FIG. 2E′ is another embodiment of FIG. 2E.

### DETAILED DESCRIPTION OF PREFERRED EMBODIMENTS

The following illustrative embodiments are provided to illustrate the disclosure of the present invention, these and other advantages and effects can be apparently understood by those in the art after reading the disclosure of this specification. The present invention can also be performed or applied by other different embodiments. The details of the specification may be described based on various viewpoints and applications, and numerous modifications and variations can be devised without departing from the spirit of the present invention.

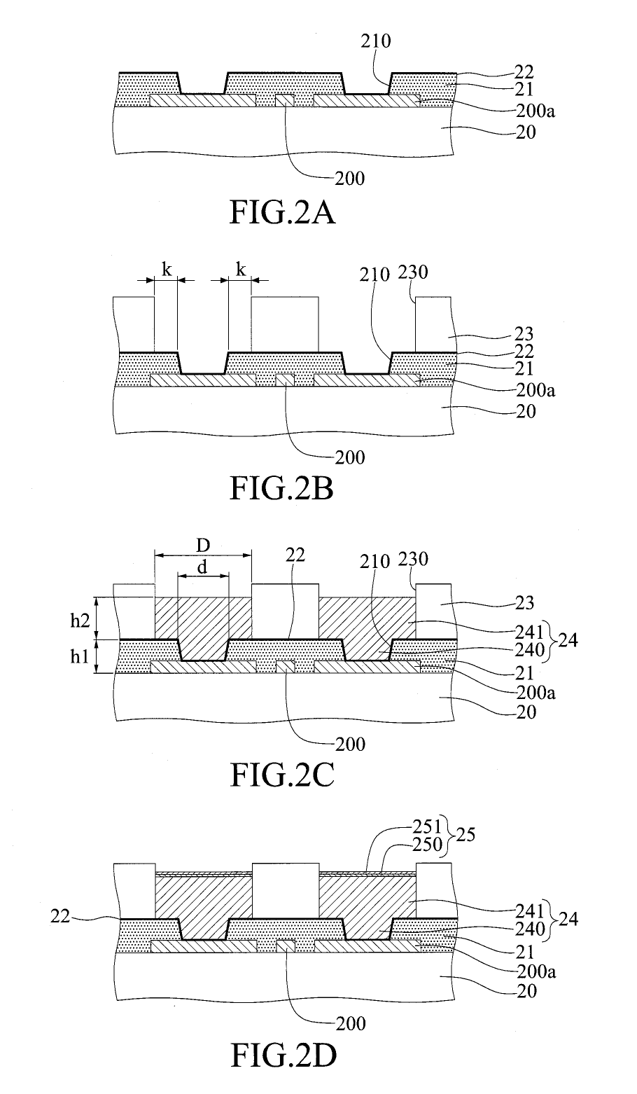

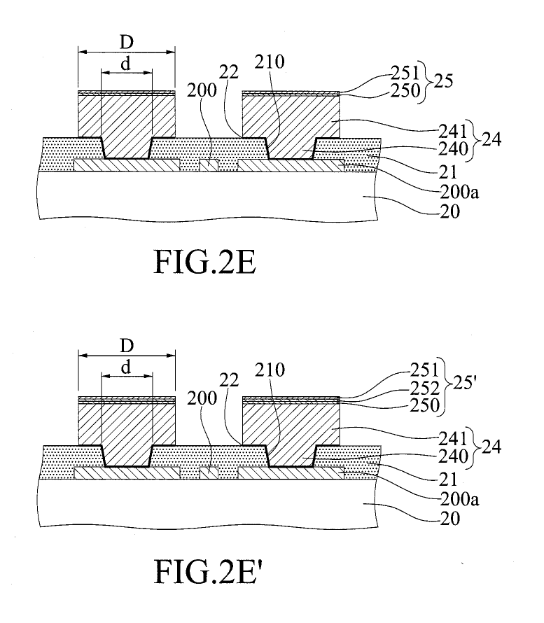

Referring to FIGS. 2A to 2E, cross-sectional views illustrating a method of fabricating a packaging substrate according to the present invention are shown.

As shown in FIG. 2A, a substrate body 20 is provided. The substrate body 20 has a circuit layer 200 and an insulating protective layer 21 formed on the substrate body 20 for covering the circuit layer 200. The circuit layer 200 has a plurality of conductive pads 200a, and the insulating protective layer 21 has a plurality of openings 210 for correspondingly exposing the conductive pads 200a.

A conductive layer 22 is then formed on the insulating protective layer 21, an opening wall of each of the openings 210, and the conductive pads 200a.

As shown in FIG. 2B, a resist layer 23 is formed on the conductive layer 22. The resist layer 23 has a plurality of opening areas 230 for exposing the openings 210 and the portion of the conductive layer 22 surrounding the openings 210. In an embodiment of the present invention, the resist layer 23 is a photoresist for being exposed and developed to form the opening areas 230.

As shown in FIG. 2C, a plurality of copper bumps 24 are formed on the conductive layer 22 in the opening areas 230. The copper bumps 24 each have a connection portion 240 formed on the conductive pad 200a in a corresponding one of the openings 210, and a protruding portion 241 integrally connected to the connection portion 240 and extending onto a portion of the insulating protective layer 21 surrounding the corresponding one of the openings 210. In an embodiment of the present invention, the connection portion 240 has a diameter d equal to 65 um, the protruding portion 241 has a diameter D equal to 95 μm, and the protruding portion 241 has a height h2 greater than a height h1 of the connection portion 240 (e.g., h2=h1×2).

As shown in FIG. 2D, top surfaces of the protruding portions 241 of the copper bumps 24 are electroplated with a surface treatment layer 25. The surface treatment layer 25 has an electroplated nickel material 250 formed on the top surfaces of the protruding portions 241 of the copper bumps 24 only, and an electroplated gold material 251 formed on the electroplated nickel material 250.

In an embodiment of the present invention, the surface treatment layer 25, which is formed by the electroplating process, has a hard and tight structure. Hence, the surface treatment layer 25 of the present invention can be thinner, as compared to the surface treatment layer 15 of the prior art, which is fabricated by the electroless-plating process. In an embodiment of the present invention, the electroplated nickel material 250 is 0.03 to 0.15 μm in thickness, and the electroplated gold material 251 is 0.20 to 0.80 μm in thickness, so as to achieve the thinning requirement. Also, the surface treatment layer 25 can still achieve a interfacial strength enough for a chip to be installed thereon during subsequent processes.

As shown in FIG. 2E, the resist layer 23 and the conductive layer 22 that is covered by the resist layer 23 are removed, to expose side surfaces of the protruding portions 241 of the copper bumps 24.

As shown in FIG. 2E′, in another embodiment of the present invention an electroplated palladium material 252 is further formed between the electroplated nickel material 250 and the electroplated gold material 251 when the surface treatment layer 25′ is formed, and the electroplated palladium material 252 is 0.05 to 0.15 μm in thickness.

During subsequent processes, an organic solderability preservative (OSP) layer may be further formed on the side surface of the surface treatment layer 25 (25′), in order to protect the exposed metal material.

In a method according to the present invention, the surface treatment layer 25 (25′) is electroplated first, and then the resist layer 23 is removed, such that the surface treatment layer 25 (25′) is not formed on the side surfaces of the protruding portions 241 of the copper bumps 24. Compared with the prior art, the protruding portion 241 according to the present invention has a diameter D irrelevant to the thickness of the surface treatment layer 25 (25′), and has a normal specification (e.g., 95 μm).

Further, since the diameter D of the protruding portion 241 keeps unchanged, the exposure alignment error (a distance k, as shown in FIG. 2B) between the opening area 230 of the resist layer 23 and the opening 210 of the insulating protective layer 21 has a preferable value (e.g., ±15 μm) during the exposure and development processes. As such, the exposure and development processes merely requires normal precision, which is advantageous for the formation of the opening areas 230.

Since the diameter of the opening area 230 is unchanged, there is no need of reducing the diameter of the opening 210. Hence, the diameter d of the connection portion 240 has a preferable value like 65 μm in the embodiment. Accordingly, the connection portion 240 is able to avoid cracks due to insufficiently bearing strength for a chip to be installed thereon.

The present invention further provides a packaging substrate, comprising a substrate body 20, a copper bump 24, and a surface treatment layer 25 (25′).

In an embodiment of the present invention, the substrate body 20 has a circuit layer 200, and an insulating protective layer 21 formed on the substrate 20 for covering the circuit layer 200. The circuit layer 200 has a plurality of conductive pads 200a. The insulating protective layer 21 has a plurality of openings 210 for correspondingly exposing the conductive pads 200a.

In an embodiment of the present invention, each of the copper bumps 24 has a connection portion 240 formed in a corresponding one of the openings 210 and electrically connected to a corresponding one of the conductive pads 200a, and a protruding portion 241 integrally connected to the connection portion 240 and extending one a portion of the insulating protective layer 21 surrounding the corresponding one of the openings 210. The protruding portion 241 has a diameter D greater than a diameter d of the connection portion 240, and the protruding portion 241 has a height h2 greater than a height h1 of the connection portion 240.

In an embodiment of the present invention, the surface treatment layer 25 has an electroplated nickel material 250 that is formed on top surfaces of the protruding portions 241 of the copper bumps 24 only, and an electroplated gold material 251 formed on the electroplated nickel material 250. The electroplated nickel material 250 is 0.03 to 0.15 μm in thickness, and the electroplated gold material 251 is 0.20 to 0.80 μm in thickness. In an embodiment of the present invention, the surface treatment layer 25′ further has an electroplated palladium material 252 formed between the electroplated nickel material 250 and the electroplated gold material 251, and the electroplated palladium material 252 is 0.05 to 0.15 μm in thickness.

In an embodiment of the present invention, the packaging substrate further comprises a conductive layer 22 formed between the copper bumps 24 and the insulating protective layer 21, and formed between the copper bumps 24 and the conductive pads 200a.

In the packaging substrate and the method of fabricating the same according to the present invention, the surface treatment layer is formed by an electroplating process, and the resist layer is then removed, such that the surface treatment layer is free from being formed on the side surfaces of the protruding portions, and the protruding portion has a diameter irrelevant to the thickness of the surface treatment layer and needs no reduction. Therefore, the alignment error between the opening area of the resist layer and the opening of the insulating protective layer has a value beneficial to the formations of the opening areas.

Further, the opening area also has an unchanged diameter and the diameter of the opening needs no reduction, such that the diameter of the connection portion is not reduced so as to keep a required strength.

The foregoing descriptions of the detailed embodiments are only illustrated to disclose the features and functions of the present invention and not restrictive of the scope of the present invention. It should be understood to those in the art that all modifications and variations according to the spirit and principle in the disclosure of the present invention should fall within the scope of the appended claims.

What is claimed is:

1. A packaging substrate, comprising:
a substrate body;
a circuit layer formed on the substrate body and having a plurality of conductive pads;
an insulating protective layer formed on the substrate body for covering the circuit layer and having a plurality of openings for correspondingly exposing the conductive pads;
a plurality of copper bumps, each of which including:
a connection portion formed in a corresponding one of the openings and electrically connected to a corresponding one of the conductive pads; and
a protruding portion integrally connected to the connection portion and extending onto a portion of the insulating protective layer surrounding the corresponding one of the openings, wherein the protruding portion is greater in diameter than the connection portion; and
a surface treatment layer including:
an electroplated nickel material formed on the protruding portion of the copper bump and having a thickness of from 0.03 to 0.15 μm; and
an electroplated gold material formed on the electroplated nickel material and having a thickness of from 0.20 to 0.80 μm.

2. The packaging substrate of claim 1, wherein the surface treatment layer further comprises an electroplated palladium material formed between the electroplated nickel material and the electroplated gold material.

3. The packaging substrate of claim 2, wherein the electroplated palladium material has a thickness of from 0.05 to 0.15 μm.

4. The packaging substrate of claim 1, further comprising a conductive layer formed between the copper bumps and the insulating protective layer and between the copper bumps and the conductive pads.

5. The packaging substrate of claim 1, wherein the protruding portion is greater than the connection portion in height.

6. A method of fabricating a packaging substrate, comprising:
providing a substrate body;
forming on the substrate body a circuit layer having a plurality of conductive pads;
forming on the substrate body an insulating protective layer for covering the circuit layer, the insulating protective layer having a plurality of openings for correspondingly exposing the conductive pads;
forming a conductive layer on the insulating protective layer, opening walls of the openings, and the conductive pads;
forming on the conductive layer a resist layer that has a plurality of opening areas for exposing the openings and a portion of the conductive layer surrounding the openings;
forming on the conductive layer in the opening areas a plurality of copper bumps, each of the copper bumps including:
a connection portion formed in a corresponding one of the openings; and
a protruding portion integrally connected to the connection portion and extending onto a portion of the insulating protective layer surrounding the corresponding one of the openings;
electroplating a surface treatment layer top surfaces of the protruding portions of the copper bumps, the surface treatment layer including:
an electroplated nickel material formed on the top surfaces of the protruding portions of the copper bumps and being of a thickness of from 0.03 to 0.15 μm; and
an electroplated gold material formed on the electroplated nickel material and being of a thickness of from 0.20 to 0.80 μm; and
removing the resist layer and the conductive layer that is covered by the resist layer, to expose side surfaces of the protruding portions of the copper bumps.

7. The method of claim 6, wherein the surface treatment layer further comprises an electroplated palladium material formed between the electroplated nickel material and the electroplated gold material.

8. The method of claim 7, wherein the electroplated palladium material is having a thickness of from 0.05 to 0.15.

9. The method of claim 6, wherein the protruding portion is greater in height than the connection portion.
